(19) United States
(12) Patent Application Publication
(10) Pub. No.: US 2026/0156891 A1
(43) Pub. Date: Jun. 4, 2026

(54) SEMICONDUCTOR STRUCTURE INCLUDING METAL GATE WITH STRESSOR MATERIAL AND METHOD FOR MANUFACTURING THE SAME

(71) Applicant: TAIWAN SEMICONDUCTOR MANUFACTURING COMPANY, LTD., Hsinchu (TW)

(72) Inventors: Shih-Hao LAI, Hsinchu (TW); Chung-Wei HSU, Hsinchu (TW); Lung-Kun CHU, Hsinchu (TW); Kuo-Cheng CHIANG, Hsinchu (TW); Chih-Hao WANG, Hsinchu (TW)

(73) Assignee: TAIWAN SEMICONDUCTOR MANUFACTURING COMPANY, LTD., Hsinchu (TW)

(21) Appl. No.: 18/965,258

(22) Filed: Dec. 2, 2024

(51) Int. Cl. H01L 21/28; H01L 21/321; H01L 29/06; H01L 29/423; H01L 29/49; H01L 29/66; H01L 29/775; H01L 29/786

(52) U.S. Cl. CPC H10D 64/01318; H10D 30/014; H10D 64/017; H10D 64/667; H10P 95/00; H10D 30/43; H10D 30/6735; H10D 30/6757; H10D 62/121

(57) ABSTRACT

A method for manufacturing a semiconductor structure includes: forming a nanosheet stack which includes sacrificial layers and channel layers; forming a gate structure; removing two stack portions of the nanosheet stack to form two source/drain recesses so that the channel layers and the sacrificial layers are respectively formed into channel features and sacrificial features; forming two source/drain portions respectively in the two source/drain recesses; removing a dummy gate of the gate structure and the sacrificial features; and forming a gate electrode which is disposed between the two source/drain portions and around the channel features, the gate electrode including an electrode material and a stressor material different from the electrode material so that a lattice distance in the channel features after forming the gate electrode is different from a lattice distance in the channel features prior to forming the gate electrode.

### BACKGROUND

An N-type field effect transistor (NFET) gains electron mobility by inducing tensile stress in channels thereof. Novel manufacturing methods are urged to increase stress in the channels, so that the NFET has a higher electron mobility, thereby improving performance of the NFET.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a flow diagram illustrating a method for manufacturing a semiconductor structure in accordance with some embodiments.

FIG. 1B is a flow diagram illustrating sub-steps of step 107 in the method for manufacturing the semiconductor structure in accordance with some embodiments.

FIGS. 2 to 25 are schematic views illustrating intermediate stages of the method for manufacturing the semiconductor structure in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “top,” “bottom,” “bottommost,” “upper,” “uppermost.” “lower,” “lowermost,” “over,” “beneath,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, or other numerical values used in the specification and claims, are to be understood as being modified in all instances by the term “about” even if the term “about” is not explicitly recited with the values, amounts or ranges. Accordingly, unless indicated to the contrary, the numerical parameters set forth in the following specification and appended claims are not and need not be exact, but may be approximations and/or larger or smaller than specified as desired, may encompass tolerances, conversion factors, rounding off, measurement error, and other factors known to those of skill in the art depending on the desired properties sought to be obtained by the presently disclosed subject matter. For example, the term “about,” when used with a value, can capture variations of, in some aspects ±20%, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions and could be understood by those skilled in the art after reviewing the present disclosure.

Source/drain portion(s) may refer to a source or a drain, individually or collectively dependent upon the context.

The present disclosure is directed to a semiconductor structure which includes a gate electrode that is capable of inducing stress in channel features, and a method for manufacturing the same. The semiconductor structure may be a field effect transistor (FET) such as a nanosheet transistor (e.g., a gate-all-around (GAA) nanosheet transistor, a forksheet nanosheet transistor), but is not limited thereto. The semiconductor structure is configured as an n-type device. The semiconductor structure includes the channel features that are stacked on each other in a vertical direction, source/drain portions that are spaced apart from each other by the channel features, and a gate electrode that surrounds each of the channel features. The gate electrode includes an electrode material and a stressor material different from the electrode material. During formation of the gate electrode, the stressor material is introduced into at least one portion of the gate electrode, so that the at least one portion of the gate electrode becomes compressive. The stressor material is oxygen, which is introduced into the at least one portion of the gate electrode through an oxidation process; or the stressor material is a selected dopant, which is introduced into the at least one portion of the gate electrode by in-situ doping during deposition process(es) of the gate electrode. The stressor material in the at least one portion of the gate electrode accounts for more than 10 atomic percentage based on total atoms in the at least one portion of the gate electrode. Such gate electrode is capable of inducing a change in lattice distance of the channel features. For instance, a lattice distance in the channel features after forming the gate electrode increases by about 0.1% to about 1.5% in comparison with a lattice distance in the channel features prior to forming the gate electrode. As such, the channel features has a higher stress level after formation of the gate electrode. Specifically, in the channel features, a tensile stress is induced in the longitudinal direction (X) (commonly known as, the channel features being tensily strained) and a compressive stress is induced in the vertical direction (Z). For instance, the channel features may have a channel strain of about 0.1 GPa to about 3 GPa, and may result in an electron mobility gain of about 4% to about 300% in the resultant semiconductor structure.

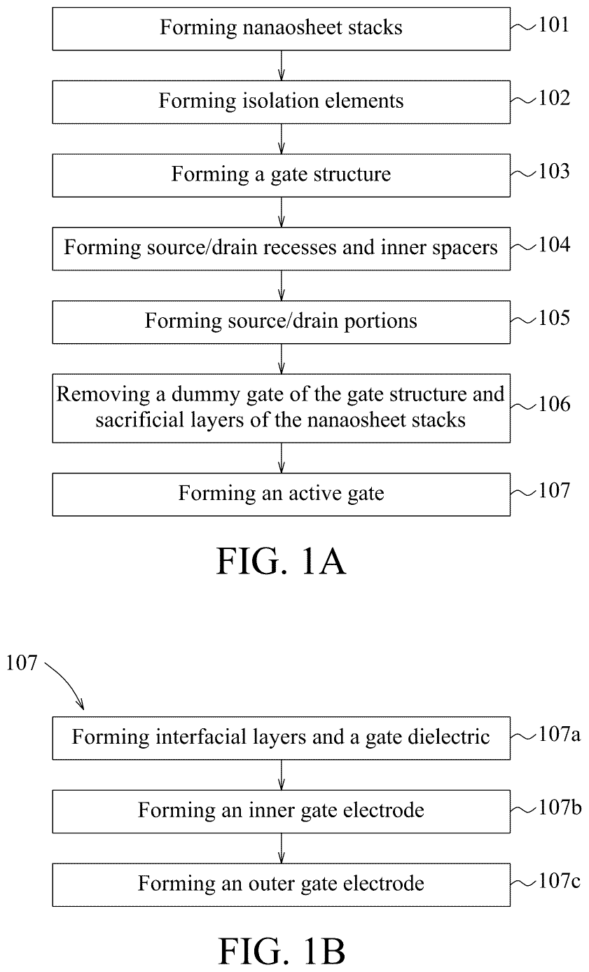

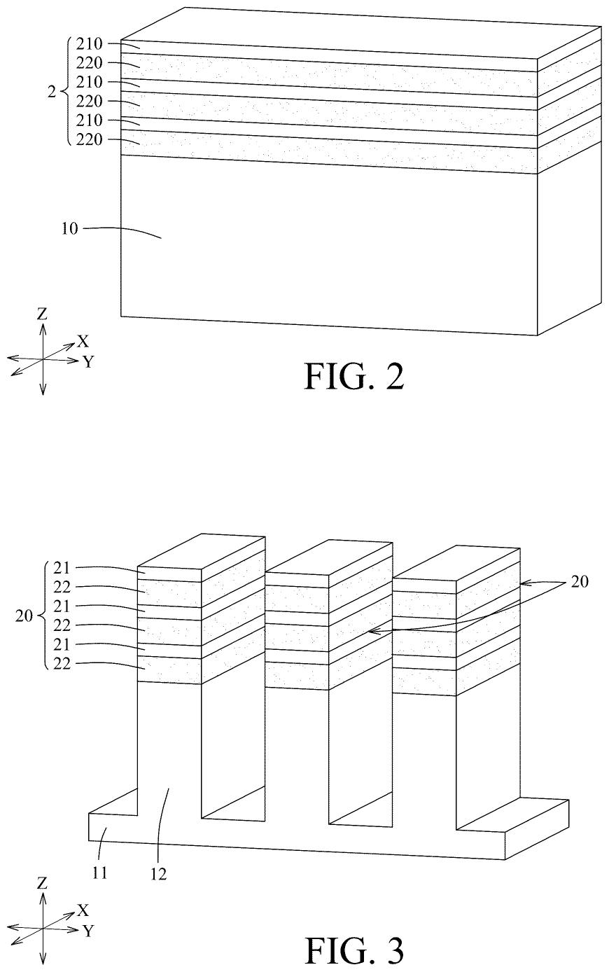

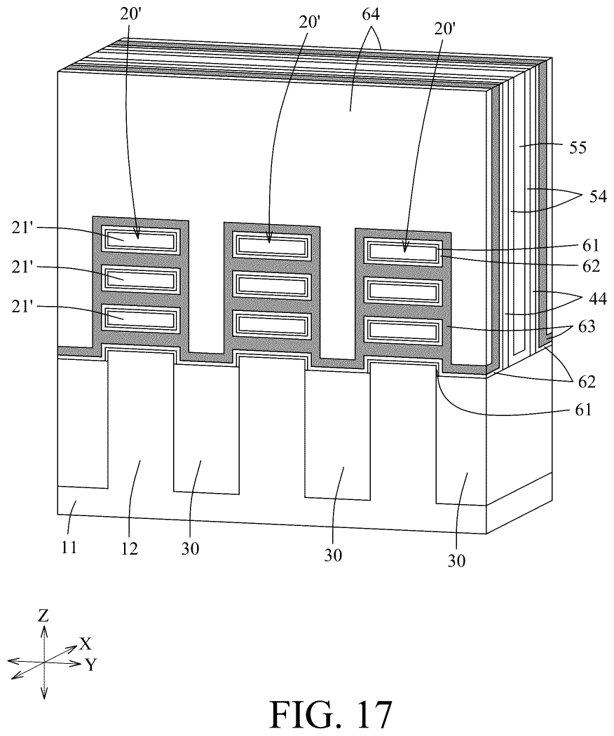

FIG. 1A is a flow diagram illustrating a method for manufacturing the semiconductor structure (for example, the semiconductor structures respectively shown in FIGS. 17, 21 and 25) in accordance with some embodiments. FIG. 1B is a flow diagram illustrating sub-steps of step 107 in the method in accordance with some embodiments. FIGS. 2 to 25 illustrate schematic views of intermediate stages of the method in accordance with some embodiments. Some repeating structures are omitted in FIGS. 2 to 25 for the sake of brevity. Additional steps can be provided before, after or during the method, and some of the steps described herein may be replaced by other steps or be eliminated.

Referring to FIG. 1A and the examples illustrated in FIGS. 2 and 3, the method begins at step 101, where nanosheet stacks 20 are formed.

Referring to FIG. 2, step 101 may include a first sub-step of forming a nanosheet material stack 2 on a substrate 10.

The substrate 10 may be made of elemental semiconductor materials, such as crystalline silicon, diamond, or germanium; compound semiconductor materials, such as silicon carbide, gallium arsenide, indium arsenide, or indium phosphide; or alloy semiconductor materials, such as silicon germanium, silicon germanium carbide, gallium arsenide phosphide, or gallium indium phosphide. The substrate 10 may be doped with p-type impurities or n-type impurities, or undoped. In addition, the substrate 10 may be a bulk silicon substrate, a silicon-on-insulator (SOI) substrate, or a germanium-on-insulator (GOI) substrate. In some embodiments, the substrate 10 may be made of silicon. Other suitable materials for forming the substrate 10 are within the contemplated scope of the present disclosure.

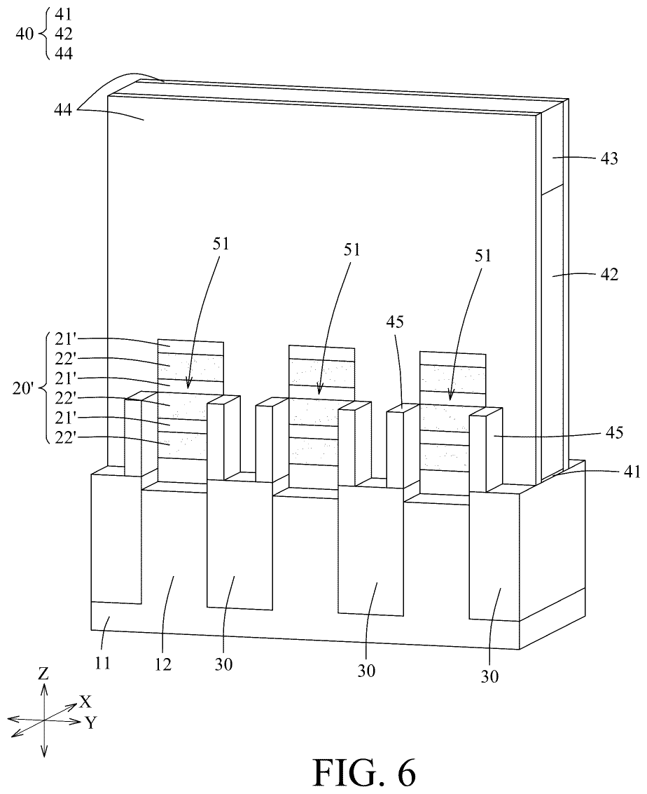

The nanosheet material stack 2 includes first nanosheet layers 210 and second nanosheet layers 220 that are alternatively stacked on each other over the substrate 10 and that may be formed using any suitable deposition processes, such as physical vapor deposition (PVD), chemical vapor deposition (CVD), atomic layer deposition (ALD), or the likes, or combinations thereof, but are not limited thereto. In the following description, a deposition process, unless otherwise stated or defined in this disclosure, may be performed in a way similar to the above-mentioned ones. The first nanosheet layers 210 will be formed into channel features 21′ (see FIG. 17) of the semiconductor structure, while the second nanosheet layers 220 are to be formed into sacrificial features 22′ (see FIG. 6) which will be removed in subsequent steps. The first nanosheet layers 210 are made of a first semiconductor material, and the second nanosheet layers 220 are made of a second semiconductor material different from the first semiconductor material. Possible materials for the first and second semiconductor materials are similar to those for the substrate 10, and thus details thereof are omitted for the sake of brevity. In some embodiments, the nanosheet material stack 2 may include three the first nanosheet layers 210, and three the second nanosheet layers 220. In certain embodiments, the first nanosheet layers 210 include silicon, while the second nanosheet layers 220 include silicon germanium. Other suitable processes, materials and/or numbers for each of the first and second nanosheet layers 210, 220 are within the contemplated scope of the present disclosure.

Referring to FIG. 3, step 101 may include a second sub-step of patterning the nanosheet material stack 2 (see FIG. 2) into the nanosheet stacks 20, and patterning the substrate 10 into fins 12 and a base 11. The fins 12 are disposed on the base 11, and are spaced apart from each other in a transverse direction (Y) by a distance ranging from about 15 nm to about 60 nm, but is not limited thereto. The second sub-step in step 101 may be performed using a patterning process which may include a photolithography process followed by an etching process. The photolithography process may include: forming a photoresist layer over a structure to be patterned by, e.g., spin coating; and patterning the photoresist layer using a photomask or without a mask (e.g., ion-beam writing). The etching process, which utilizes the patterned photoresist layer as an etching mask, may include etching the structure to be patterned by, for example, dry etching, wet etching, or a combination thereof. In the following description, a patterning process, unless otherwise stated or defined in this disclosure, may be performed in a way similar to the above-mentioned ones. In some embodiments, masking layers (not shown) for patterning the nanosheet material stack 2 into the nanosheet stacks 20 may remain on the nanosheet stacks 20, respectively. Each of the fins 12 extends in a longitudinal direction (X) transverse to (e.g., perpendicular to) the transverse direction (Y). The nanosheet stacks 20 are respectively disposed on the fins 12 opposite to the base 11 in a vertical direction (Z) transverse to (e.g., perpendicular to) the transverse direction (Y) and the longitudinal direction (X). The nanosheet stacks 20 are spaced apart from each other. The first nanosheet layers 210 (see FIG. 2) are patterned to form the channel layers 21 of the nanosheet stacks 20; and the second nanosheet layers 220 (see FIG. 2) are patterned to form the sacrificial layers 22 of the nanosheet stacks 20. Each of the channel layers 21 may have a width (measured in the transverse direction (Y)) ranging from 5 nm to about 100 nm; and a height (measured in the vertical direction (Z)) ranging from about 4 nm to about 10 nm, but are not limited thereto. Each of the sacrificial layers 22 may have a height (measured in the vertical direction (Z)) ranging from about 4 nm to about 15 nm, but is not limited thereto. Such dimension ranges are found to facilitate increased stability of process flow of the semiconductor structure. Other suitable processes and/or dimensions for the channel layers 21 and the sacrificial layers 22 are within the contemplated scope of the present disclosure.

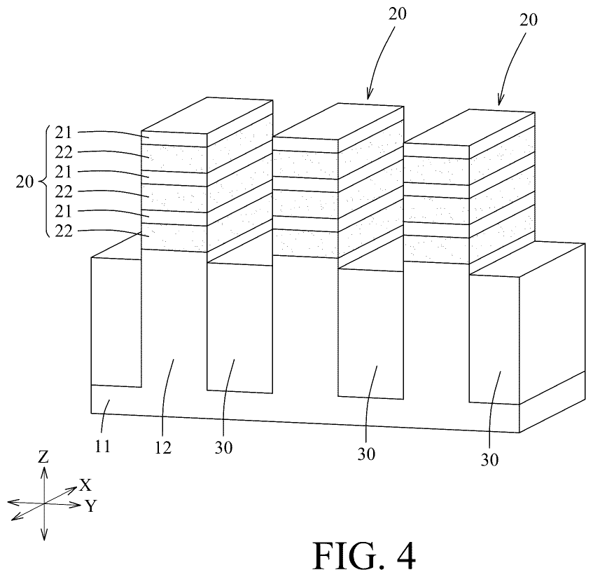

Referring to FIG. 1A and the example illustrated in FIG. 4, the method proceeds to step 102, where isolation elements 30 are formed.

Each of the isolation elements 30 is formed on the base 11 between two adjacent ones of the fins 12. Such isolation elements 30 may also be known as shallow trench isolations (STI). The isolation elements 30 may be formed by: depositing an isolation material for forming the isolation elements 30 using any suitable deposition processes over the structure shown in FIG. 2 such that the isolation material fills spaces among the nanosheet stacks 20; performing a planarization process (e.g., chemical mechanical polishing (CMP)) to obtain a planarized surface, through which the masking layers (not shown) remaining respectively on the nanosheet stacks 20 may be exposed; and etching back the isolation material using any suitable etching processes, such as dry etching, wet etching, anisotropic etching, or combinations thereof. In the following description, an etching process, unless otherwise stated or defined in this disclosure, may be performed in a way similar to the above-mentioned ones. In some embodiments, upper surfaces of the isolation elements 30 may be at a level lower than a level of upper surfaces of the fins 12. In some embodiments, the isolation elements 30 include a dielectric material, such as an oxide-based dielectric (e.g., silicon oxide), but is not limited thereto. Other suitable processes, materials and/or configurations of the isolation elements 30 are within the contemplated scope of the present disclosure.

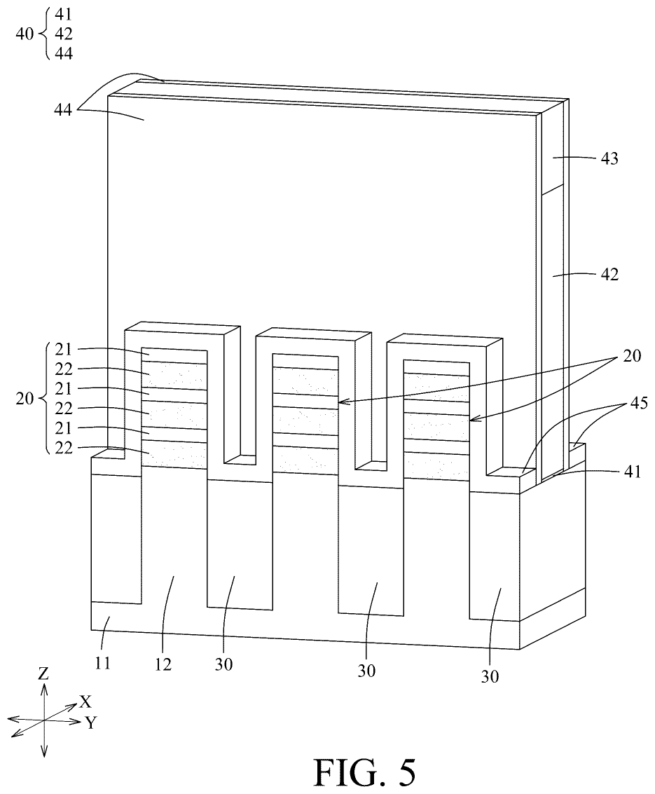

Referring to FIG. 1A and the examples illustrated in FIG. 5, the method proceeds to step 103, where a gate structure 40 is formed over the nanosheet stacks 20 in the transverse direction (Y).

Step 103 may include a first sub-step of forming a stack including a dummy gate dielectric 41, a dummy gate electrode 42, and a mask 43 over the nanosheet stacks 20 and the isolation elements 30. In some embodiments, the first sub-step in step 103 is performed by: depositing first and second dummy layers (not shown) respectively for forming the dummy gate dielectric 41 and the dummy gate electrode 42 using any suitable deposition processes; performing a planarization process (e.g., CMP) to obtain a planar upper surface of the second dummy layer (i.e., a planarized second dummy layer); forming a third dummy layer (not shown) for forming the mask 43 on the planarized second dummy layer using any suitable deposition processes; and patterning the first dummy layer, the planarized second dummy layer and the third dummy layer to partially expose the fins 12 and the isolation elements 30 using any suitable patterning processes and/or etching processes. The dummy gate dielectric 41 and the dummy gate electrode 42 cooperatively serve as a dummy gate of the gate structure 40. Step 103 may include a second sub-step of forming two gate spacers 44 over the nanosheet stacks 20 and the isolation elements 30 respectively on two sides of the stack that are opposite to each other in the longitudinal direction (X). The dummy gate and the two gate spacers 44 cooperatively serve as the gate structure 40. As such, in each of the nanosheet stacks 20, two stack portions are respectively located at two opposite sides of the gate structure 40 in the longitudinal direction (X). In some embodiments, step 103 further includes a third sub-step of forming fin sidewall layers 45 each covering one of the two stack portions of the nanosheet stacks 20, as well as the isolation elements 30. In some embodiments, the second and third sub-steps are performed simultaneously by depositing a spacer material layer for forming the gate spacers 44 and the fin sidewall layers 45 using any suitable deposition processes, and patterning the spacer material layer by any suitable patterning processes and/or etching processes. Other suitable processes for forming the dummy gate dielectric 41, the dummy gate electrode 42, the mask 43, the gate spacers 44 and the fin sidewall layers 45 are within the contemplated scope of the present disclosure.

The dummy gate dielectric 41 may include a dielectric material, such as silicon oxide, or the likes. The dummy gate electrode 42 may include polycrystalline silicon, or the likes. The mask 43 may be a single layer structure, or a multi-layered structure. The mask 43 may include a dielectric material, such as silicon nitride, silicon oxide, silicon oxynitride, or the likes, or combinations thereof. The gate spacers 44 and the fin sidewall layers 45 may be made of a same or different material, and may include a dielectric material, such as a silicon carbon-containing dielectric material, a silicon oxide-containing material, silicon nitride, other suitable materials, or combinations thereof. Other suitable materials for each of the dummy gate dielectric 41, the dummy gate electrode 42, the mask 43, the gate spacers 44 and the fin sidewall layers 45 are within the contemplated scope of the present disclosure.

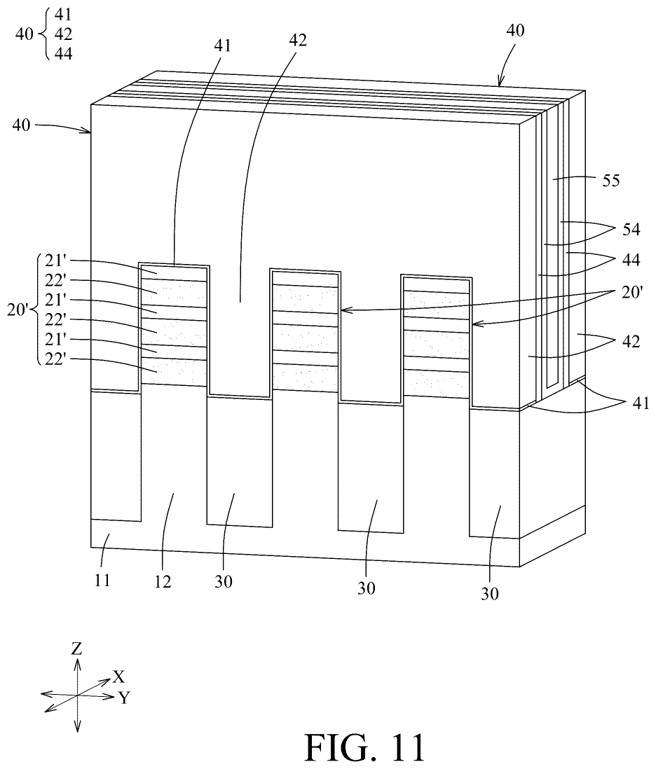

As shown in FIG. 5, only one the gate structure 40 is shown, while two or more of the gate structures 40 may be formed to be spaced apart from each other in the longitudinal direction (X) (see also FIG. 11).

Referring to FIG. 1A and the examples illustrated in FIGS. 6 to 8, the method proceeds to step 104, where source/drain recesses 51 and inner spacers 52 are formed.

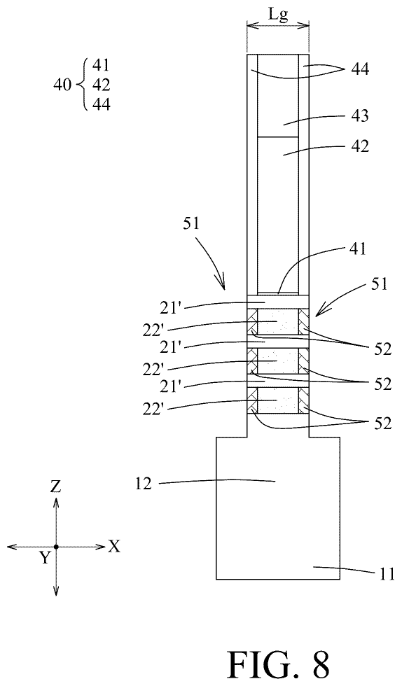

Step 104 may include a first sub-step of patterning the fin sidewall layers 45 shown in FIG. 5 into fin sidewalls (see FIG. 6, also denoted by the numeral 45) using any suitable patterning processes and/or etching processes so as to expose the stack portions of the nanosheet stacks 20 (see FIG. 5). Referring to FIG. 6, step 104 may include a second sub-step of patterning the nanosheet stacks 20 (see FIG. 5), so as to remove the stack portions and to form source/drain recesses 51 at opposite sides of each of the gate structures 40 so that the channel layers 21 are formed into channel features 21′ and the sacrificial layers 22 are formed into sacrificial features 22′. Hereinafter, the nanosheet stacks, after step 104, are denoted by the numeral 20′. In some embodiments, the second sub-step of step 104 may be performed by any suitable patterning processes and/or etching processes while the mask 43 is provided to protect the dummy gate (i.e., the dummy gate dielectric 41 and the dummy gate electrode 42). In some embodiments, each of the channel features 21′ has a length (Lg) (see FIG. 8), measured in the longitudinal direction (X) and determined by a width of a corresponding one of the dummy gate structures 40), ranging from about 8 nm to about 30 nm, but is not limited thereto. Specifically, two of the source/drain recesses 51 are formed at opposite sides of each of the nanosheet stacks 20′ in the longitudinal direction (X). In some embodiments, upper portions of the fins 12 are also removed in the second sub-step of step 104. Other suitable sub-steps and/or processes for forming the source/drain recesses 51 and other suitable dimensions for the channel features 21′ are within the contemplated scope of the present disclosure.

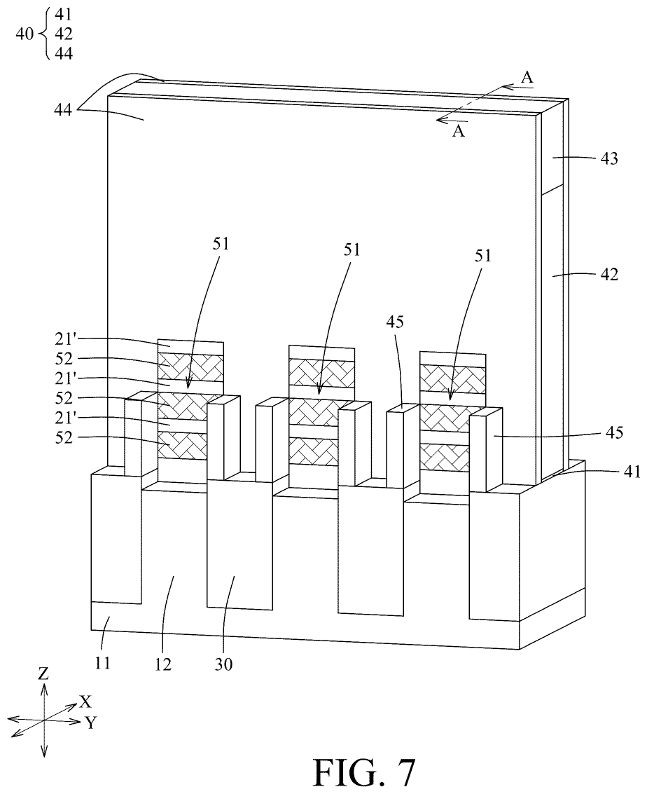

Step 104 may include a third sub-step of removing end regions of each of the sacrificial features 22′ (see FIG. 6) that are opposite to each other in the longitudinal direction (X). The end regions of each of the sacrificial features 22′ may be removed using any suitable etching processes. Hereinafter, the remaining sacrificial features are also denoted by the numeral 22′. FIG. 8 is a cross-sectional view (x-cut) of the structure taken along the line A-A shown in FIG. 7. Referring to FIGS. 7 and 8, step 104 may include a fourth sub-step of forming the inner spacers 52, such that two of the inner spacers 52 are respectively formed at two opposite sides of each of the remaining sacrificial features 22′ in the longitudinal direction (X). The inner spacers 52 may include a dielectric material such as silicon oxide, silicon nitride, silicon oxynitride, silicon carbide, or the likes, or combinations thereof. Other suitable materials and/or processes for forming the inner spacers 52 are within the contemplated scope of the present disclosure.

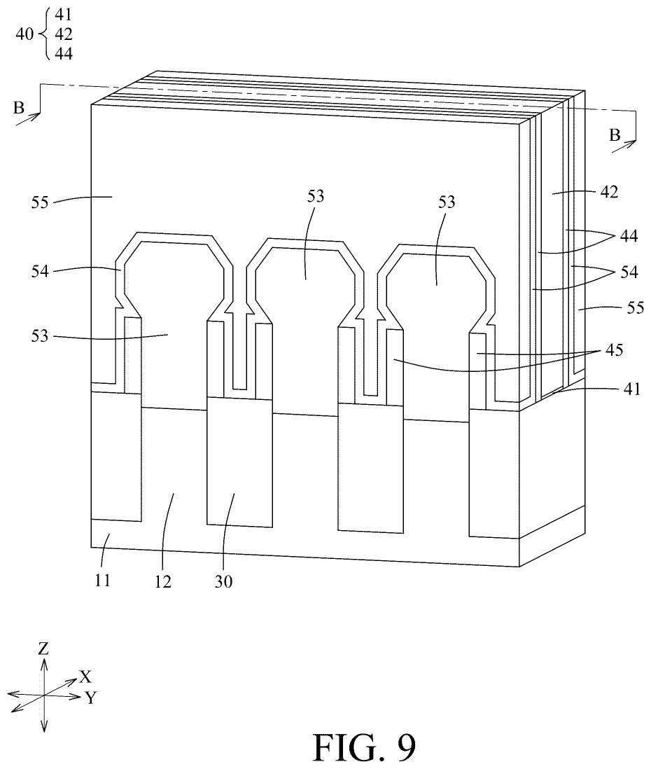

Referring to FIG. 1A and the example illustrated in FIG. 9, the method proceeds to step 105, where source/drain portions 53 are respectively formed in the source/drain recesses 51 (see FIGS. 7 and 8).

Step 105 may include a first sub-step of forming the source/drain portions 53 respectively in the source/drain recesses 51 using e.g., an epitaxy growth process, but is not limited thereto. In some embodiments, the source/drain portions 53 may include single or multiple epitaxy layers. In certain embodiments, the source/drain portions 53 may include silicon, silicon germanium, other suitable materials, or combinations thereof. In other embodiments, the source/drain portions 53 may include any suitable dopants (such as n-type dopant(s), or p-type dopant(s)). Other suitable materials and/or processes for forming the source/drain portions 53 are within the contemplated scope of the present disclosure. In an exemplary embodiment, since the semiconductor structure shown in FIG. 17 is an n-type device, the source/drain portions 53 may include silicon, and are optionally doped with n-type dopant(s). Other suitable materials and/or processes for forming the source/drain portions 53 are within the contemplated scope of the present disclosure.

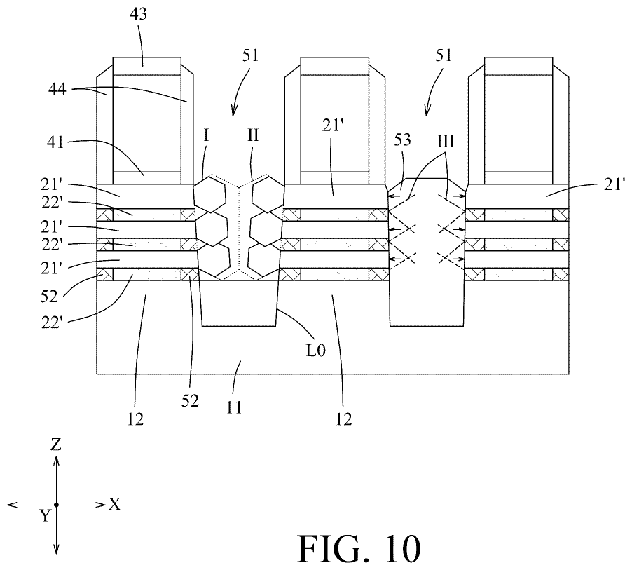

FIG. 10 illustrates different stages of the epitaxy growth process of the source/drain portions 53. In the left source/drain recess 51, two early stages after L0 (e.g., L1, L2, and so on) of the epitaxy growth process are shown respectively in solid lines labeled (I) and dotted lines labeled (II), while in the right source/drain recess 51, a final stage of the epitaxy growth process is shown. In L0, a bottom section of each of the source/drain portions 53 is grown from a corresponding one of the fins 12 (see the region labeled (L0)). After L0, in an initial stage of the epitaxy growth process, sections of each of the source/drain portions 53 respectively originate and grow from L0, and the channel features 21′ of two adjacent corresponding ones of the nanosheet stacks 20 (see the solid lines labeled (I), the sections grown from L0 are not shown in figures). In a middle stage of the epitaxy growth process, the different sections continue growing and start to merge and stack on one another (see the dotted lines labeled (II)). In a final stage of the epitaxy growth process, the different sections of each of the source/drain portions 53 continue growing and merging to eventually form an integrated piece that entirely fills a corresponding one of the source/drain recesses 51, thereby obtaining the source/drain portions 53. Although the sections formed in the initial stage have good crystal quality, in the middle stage and the final stages, crystal quality at interfaces (see the dashed lines labeled (III)), where the different sections join each other, may be less satisfactory, i.e., defects arise in the source/drain portions 53 thus obtained. Such defects may be known as stacking faults of the source/drain portions 53, resulting in a poor stressor quality of the source/drain portions 53. That is, the source/drain portions 53 induce less stress in the channel features 21′ (see the arrows in the right source/drain portion 53 of FIG. 10), thus electron mobility is undesirably reduced.

Referring back to FIG. 9, step 105 may further include a second sub-step of sequentially forming dielectric structures each including a contact etch stop layer (CESL) 54 and an interlayer dielectric (ILD) 55 over the source/drain portions 53, the fin sidewalls 45 and the isolation elements 30. The dielectric structures are formed to alternate with the gate structures 40 (only one is shown in FIG. 9), i.e., two dielectric material layers respectively for forming the CESL 54 and the ILD 55 are formed over the structure obtained in the first sub-step of step 105 using any suitable disposition processes, followed by removing an excess of the two dielectric material layers using a planarization process (e.g., CMP) to expose the dummy gate electrode 42, thereby removing the mask 43 (see FIGS. 7 and 8) accordingly. Each of the CESL 54 and the ILD 55 may include a dielectric material such as silicon oxide, silicon nitride, phosphosilicate glass, borophosphosilicate glass, spin-on glass, fluorosilicate glass, carbon-doped silicon oxide, xerogel, aerogel, parylene, divinylsiloxane-bis-benzocyclobutene-based dielectric material, polyimide, or the like, or combinations thereof. The CESL 54 and the ILD 55 may include different dielectric materials. Other suitable materials and processes for forming the CESL 54 and the ILD 55 are within the contemplated scope of the present disclosure.

FIG. 11 is a cross-sectional view (y-cut) of the structure taken along the line B-B shown in FIG. 9, at which the nanosheet stacks 20′ (including the remaining sacrificial features 22′ and the channel features 21′), the gate structures 40, the fins 12 and the isolation elements 30 are shown.

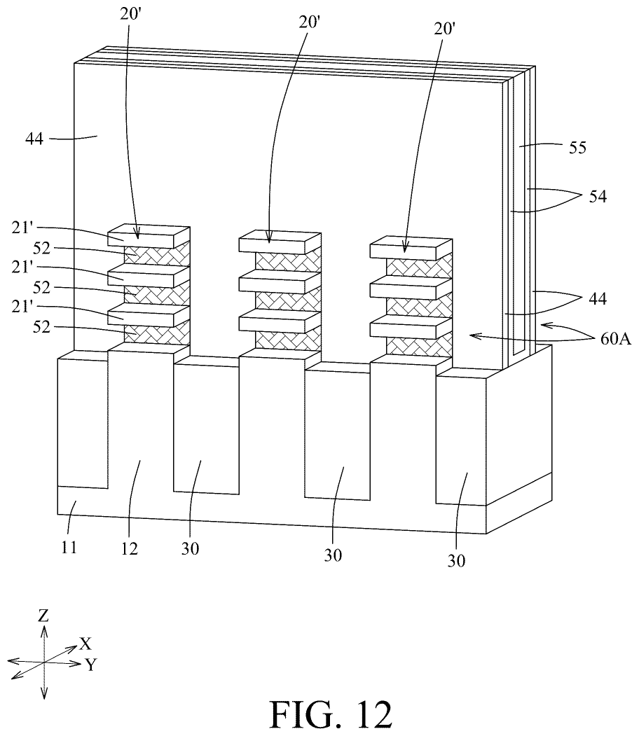

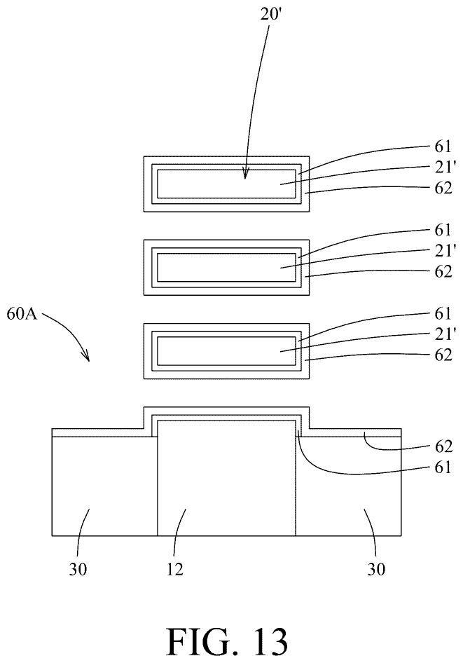

Referring to FIG. 1A and the example illustrated in FIG. 12, the method proceeds to step 106, where the dummy gate, i.e., the dummy gate dielectric 41 and the dummy gate electrode 42, of each of the gate structures 40, and the remaining sacrificial features 22′ are removed (see also FIG. 11), so as to form cavities 60A that will accommodate active gates formed in subsequent step.

The dummy gate and the remaining sacrificial features 22′ may be removed using any suitable etching processes. Other suitable processes for removing the dummy gate and the sacrificial features 22′ are within the contemplated scope of the present disclosure. After step 106, the channel features 21′, the fins 12, and the inner spacers 52 are exposed from the gate spacers 44.

Referring to FIG. 1A and the examples illustrated in FIGS. 13 to 17, the method proceeds to step 107, where the active gates are formed.

FIG. 17 is a perspective view of the semiconductor structure after completing step 107 in accordance with some embodiments. Referring to FIG. 17, each of the active gates includes a gate dielectric 62, a gate electrode 63 and a filling electrode 64 that are sequentially formed to fill the cavity 60A (see also FIG. 12). It is noted that the cavities 60A shown in FIG. 12 are formed in positions corresponding to the dummy gates and the remaining sacrificial features 22′ shown in FIG. 11. The gate electrode 63 is more proximal to the channel features 21′ in comparison to the filling electrode 64, i.e., the filling electrode 64 is formed on the gate electrode 63 opposite to the channel features 21′. The gate electrode 63 is configured to induce stress, and thus lattice change in the channel features 21′, to thereby enhance electron mobility.

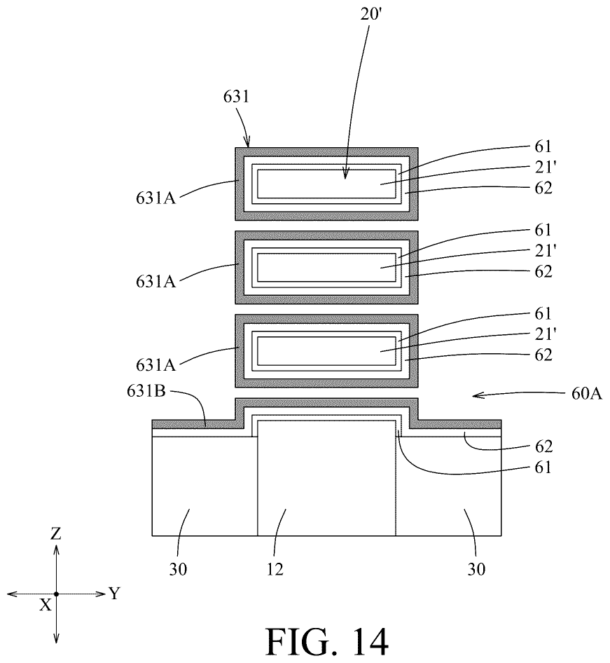

Referring to FIGS. 1B and 13, step 107 may include a first sub-step 107a of (i) forming interfacial layers (ILs) 61 respectively around the channel features 21′ and over the fins 12; followed by (ii) forming a gate dielectric 62 over the ILs 61, the isolation elements 30 and the gate spacers 44 (see also FIG. 17). FIG. 13 is a partial view of a y-cut of the structure obtained after completing the first sub-step 107a, in which only one of the nanosheet stacks 20′, an upper portion of a corresponding one of the fins 12, and portions of two adjacent corresponding ones of the isolation elements 30 are shown, while other elements of the structure are omitted. FIGS. 14 to 16 are also partial views of structures obtained subsequent to the structure shown in FIG. 13. In some embodiments, the ILs 61 are formed using CVD, ALD, thermal oxidation, or wet chemical oxidation. In some embodiments, the gate dielectric 62 are formed using CVD or ALD. Other suitable techniques for forming the ILs 61 and the gate dielectric 62 are within the contemplated scope of the present disclosure.

Each of the ILs 61 may serve as a buffer layer for facilitating growth of a next layer (i.e., the gate dielectric 62) thereon, and may include a dielectric material such as silicon oxide, silicon nitride, silicon oxynitride, or combinations thereof, but is not limited thereto. The gate dielectric 62 may include a high dielectric constant material, such as a hafnium-based dielectric material, or the like, but is not limited thereto. Each of the ILs 61 may have a thickness ranging from about 0.5 nm to about 2 nm. The gate dielectric 62 may have a thickness ranging from about 1 nm to about 2 nm. Other suitable materials and/or thickness ranges of the ILs 61 and/or the gate dielectric 62 are within the contemplated scope of the present disclosure.

Referring to FIG. 1B, step 107 may then include a second sub-step 107b of forming the gate electrode 63 that includes or is made of a first electrode material. Referring to FIG. 14, forming the gate electrode 63 includes a first stage of depositing the first electrode material over the structure shown in FIG. 13 to form an electrode material layer 631. Any suitable deposition processes known in the art may be adopted. It is noted that the electrode material layer 631 is merely a thin film having a thickness ranging from about 1 nm to about 5 nm. The thickness is limited by a distance between adjacent ones of the channel features 21′, and is designed to achieve a desired electrical properties of the resultant gate electrode 63. Specifically, the electrode material layer 631 has (i) electrode portions 631A that are respectively formed around the channel features 21′ of each of the nanosheet stacks 20′ (only one nanosheet stack 20′ is shown in FIG. 14); (ii) a bottom portion 631B that is formed over the fins 12 (one of the fin 12 is shown) and the isolation elements 30; and (iii) a vertical portion (not shown) that interconnects the electrode portions 631A and the bottom portion 631B. The electrode portions 631A and the bottom portion 631B are spaced apart from each other in the vertical direction (Z). In some embodiments, the bottom portion 631B and each of the electrode portions 631A are spaced apart by a distance ranging from about 1 nm to about 5 nm, so as to allow sufficient space for expansion of the first electrode material in subsequent sub-step. It should be noted that in FIG. 14, only one of the nanosheet stacks 20′ is shown in each of the cavities 60A, and indeed several nanosheets 20′ are located in each of the cavities 60A (see also FIG. 12). In some embodiments, in each of the cavities 60A, the electrode portions 631A are respectively formed around corresponding ones of the channel features 21′ of the nanosheet stacks 20′, the bottom portion 631B is formed on corresponding portions of the fins 12 and corresponding portions of the isolation elements 30, and the vertical portion is formed on two corresponding adjacent ones of the gate spacers 44 (only one of the two corresponding adjacent ones of the gate spacers 44 is shown in FIG. 12) and corresponding ones of the inner spacers 52.

Examples of the first electrode material are titanium nitride (TiN), tantalum nitride (TaN), titanium silicon nitride (TiSiN), tungsten carbon nitride (WCN), molybdenum (Mo), titanium aluminum (TiAl), titanium aluminum carbide (TiAlC), titanium aluminum silicon carbide (TiAl(Si)C), tantalum aluminum carbide (TaAlC), tantalum aluminum silicon carbide (TaSiAlC), or the likes, or combinations thereof, but are not limited thereto. Other suitable materials are within the contemplated scope of the present disclosure.

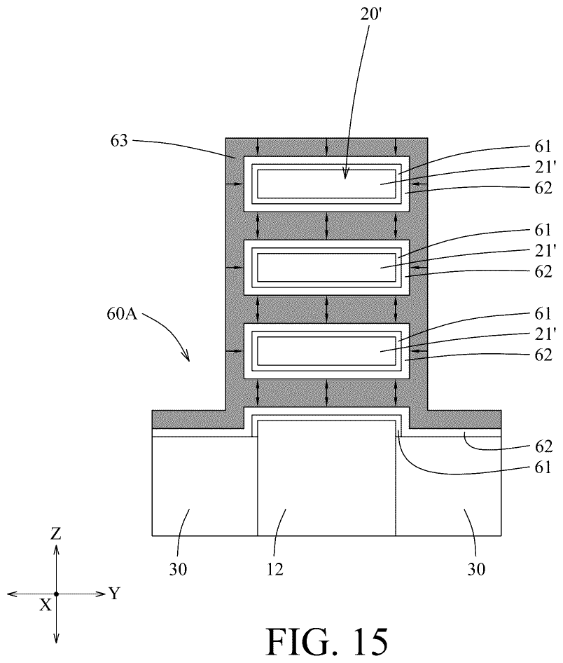

Referring to FIGS. 14 and 15, forming the gate electrode 63 includes a second stage of subjecting the electrode material layer 631 to an oxidation process, such that oxygen is introduced into the first electrode material to form an oxide of the first electrode material. In such case, oxygen serves as the stressor material to expand the first electrode material (i.e., expansion of the first electrode layer 631). It is noted that, as the oxidation process proceeds, the different portions of the electrode material layer 631 continue to expand, and eventually, the electrode portions 631A and the bottom portion 631B merge in a continuous manner, thereby obtaining the gate electrode 63 as shown in FIG. 15. The gate electrode 63 serves as a compressive film, and results from the insertion of the stressor material into the first electrode material. Such compressive film induces a lattice change in the channel features 21′. Specifically, after formation of the gate electrode 63, a lattice distance between adjacent silicon atoms of the channel features 21′ in the longitudinal direction (X) is lengthened, i.e., a tensile stress is induced in the longitudinal direction (X), or in other words, the channel features 21′ are tensily strained. Such tensile stress is found to significantly enhance electron mobility of the semiconductor structure. In addition, as shown by the arrows in the vertical direction (Z) in FIG. 15, a compressive stress is also induced in the vertical direction (Z), which also facilitates enhancement of electron mobility of the semiconductor structure. The gate electrode 63 includes inner electrode portions and an outer electrode portion. Each of the inner electrode portions is located between two adjacent ones of the channel features 21′ or between a bottommost one of the channel features 21 and the fin 12. The outer electrode portion covers the inner electrode portions, the channel features 21, the fin 12 and the isolation elements 30. In some embodiments, in the oxidation process or other suitable processes for introducing the stressor material described hereinafter, the inner electrode portions and the outer electrode portion are treated by the stressor material uniformly.

It should be noted that conditions for performing the oxidation process is carefully monitored, e.g., by controlling temperature, time period etc., so as to effectively introduce oxygen into the first electrode material (so as to obtain the gate electrode 63 that is capable of inducing sufficient stress in the channel features 21′), and at the same time minimizes impacts, if any, brought to underlying elements in the structure. For instance, the stressor material is absent from the gate dielectric 62 or the channel features 21′, or oxygen content of the gate dielectric 62 or the channel features 21′ remains at substantially similar level prior to and after forming the gate electrode 63.

The oxidation process may be performed by various approaches. In some embodiments, the oxidation process is a soaking process, in which the structure shown in FIG. 14 is immersed in a relatively low oxygen content environment (optionally in presence of nitrogen), e.g., similar to an oxygen content of air, for a relatively long period of time (e.g., approximately several seconds, but is not limited thereto) at a temperature ranging from about 300° C. to about 800° C. In other embodiments, the oxidation process is a spiking process, in which the structure shown in FIG. 14 is immersed in a relatively high oxygen content environment, e.g., in which oxygen content is higher than that of air, for a relatively short period of time (e.g., approximately less than 1 second, but is not limited thereto) at a temperature ranging from about 800° C. to about 1000° C. In certain embodiments, the structure shown in FIG. 14 is subjected to a plasma treatment using oxygen and nitrogen for about 10 seconds to about 150 seconds at a temperature ranging from about 100° C. to about 300° C. (which may be known as an “O-ash” process). In yet other embodiments, a suitable wet chemical is applied to react with the first electrode material for about 10 seconds to about 300 seconds at a temperature ranging from about room temperature to about 50° C. Examples of the wet chemical are deionized ozone, deionized carbon dioxide, water, but are not limited thereto. Other suitable processes, and/or conditions, and/or chemicals for performing the oxidation process are within the contemplated scope of the present disclosure.

After the oxidation process, in some embodiments, the stressor material, i.e., oxygen, accounts for about 20 atomic percentage to about 50 atomic percentage based on 100 atomic percentage of the first electrode material and the stressor material. In this case, the oxygen accounts for about 20 atomic percentage to about 50 atomic percentage based on total atoms in the gate electrode 63. When such amount of oxygen is introduced into the first electrode material, the resultant gate electrode 63 is ensured to be sufficiently compressive to induce sufficient amount of tensile stress in the channel features 21′ (i.e., the channel features 21′ are tensily strained); and that electrical properties of the resultant gate electrode 63 are less impacted. In other cases where the oxidation process as described above is not performed, oxygen may account for less than about 10 atomic percentage based on total atoms in the gate electrode 63. In some embodiment, oxygen is distributed among the first electrode material throughout the entire gate electrode 63, so as to ensure uniform electrical properties of the gate electrode 63. After completing the second stage, the gate electrode 63 is obtained. In addition, oxygen content of other elements of the structure, e.g., the channel features 21′, the gate dielectric 62, the ILs 61, remains at similar level after formation of the gate electrode 63, indicating that the oxidation process is controlled such that the other elements of the structure are merely minimally affected.

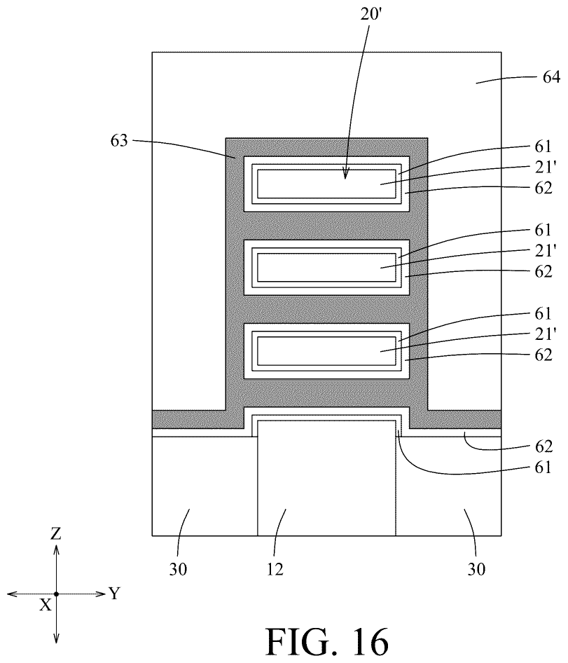

Referring to FIGS. 16 and 17, step 107 may include a third sub-step 107c of forming the filling electrode 64. The filling electrode 64 is formed by depositing a second electrode material over the structure obtained in the second sub-step 107b using any suitable deposition processes, such that the second electrode material fills each of the cavities 60A (see also FIGS. 12 and 15), followed by a planarization process (e.g., CMP) to expose the CESL 54 and the ILD 55. Afterwards, the active gates each including the filling electrode 64, the gate electrode 63, the gate dielectric 62 are obtained. In some embodiments, the oxygen accounts for less than about 10 atomic percentage based on total atoms in each of the filling electrode 64 and the channel features 21′.

In some embodiments, the filling electrode 64 includes the second electrode material, which may be the same as or different from the first electrode material. In other embodiments, the second electrode material includes a conductive material such as a metal, a metal-containing nitride, a metal-containing silicide, a metal-containing carbide, or the likes, but are not limited thereto. Other suitable materials for forming the filling electrode 64 are within the contemplated scope of the present disclosure.

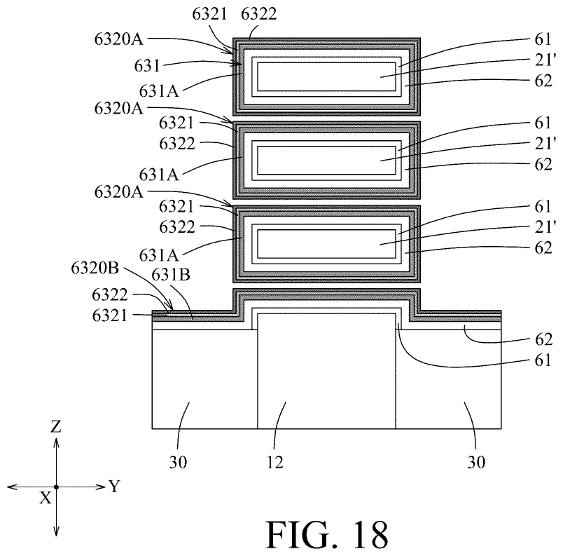

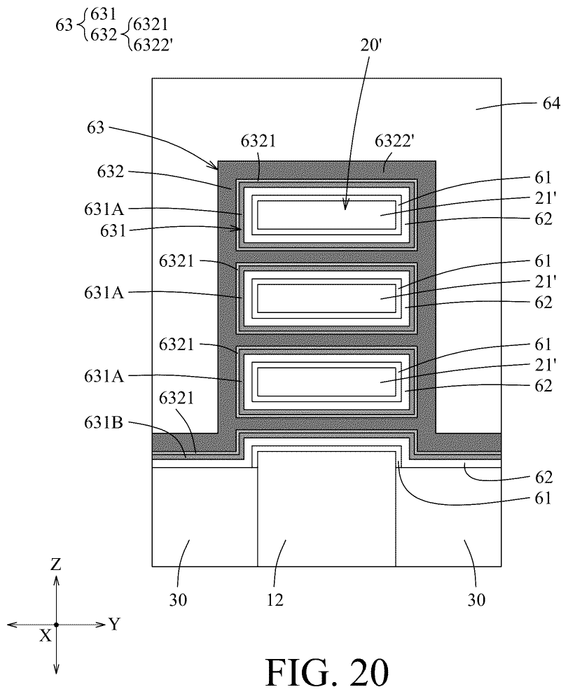

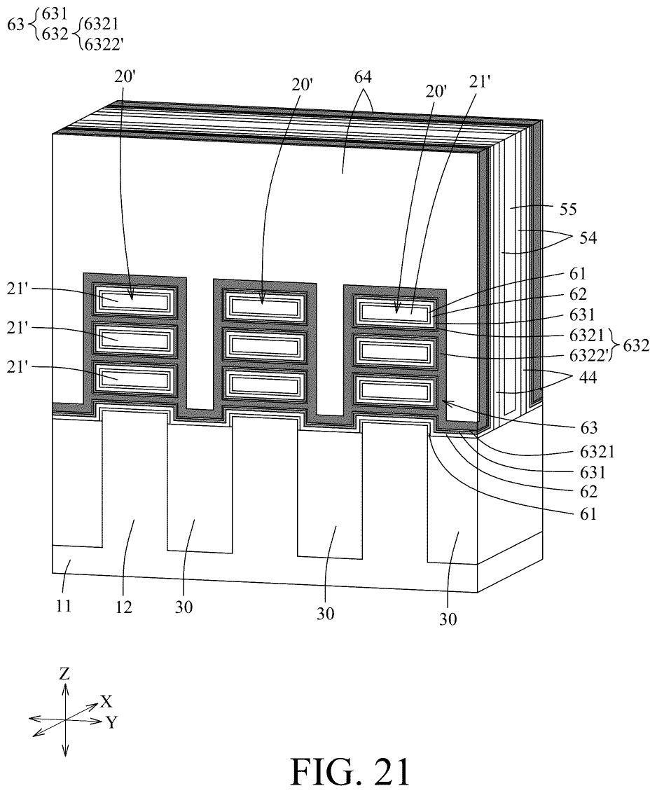

In some embodiments, the second sub-step 107b of forming the gate electrode 63 may be modified to further form a stressor feature 632 (see FIG. 21) within the gate electrode 63 for inducing stress in the channel features 21′. The stressor feature 632 includes an inner material (for forming an inner material layer), and an outer material (for forming an outer material layer). Specifically, the stressor material is introduced into the outer material, instead of into the first electrode material of the electrode material layer 631. FIGS. 18 to 21 are views corresponding to those of FIGS. 14 to 17, and show structures which are obtained after modifications to the second and third sub-steps 107b, 107c for forming the stressor feature 632 within the gate electrode 63 (see FIGS. 20 and 21).

Referring to FIG. 18, the first stage of the second sub-step 107b may further include sequentially depositing the inner material and the outer material over the electrode material layer 631 so as to respectively form the inner material layer 6321 and the outer material layer 6322 that are located on the electrode material layer 631 opposite to the channel features 21′ (and the fin 12, and the gate spacer 44 (not shown)). Specifically, portions of the inner material layer 6321 and the outer material layer 6322 that are respectively located around the electrode portions 631A cooperatively form stressor portions 6320A. Other portions of the inner material layer 6321 and the outer material layer 6322 that are formed over the bottom portion 631B cooperatively form a stressor bottom portion 6320B. Yet other portions of the inner material layer 6321 and the outer material layer 6322 that interconnect the stressor portions 6320A and the stressor bottom portion 6320B cooperatively form a stressor vertical portion (not shown). The stressor portions 6320A and the stressor bottom portion 6320B are spaced apart from each other by a distance ranging from about 1 nm to about 5 nm, so as to allow sufficient space for expansion of the outer material (i.e., for expansion of the stressor portions 6320A, the stressor bottom 6320B and the stressor vertical portion) in subsequent sub-step.

The first electrode material and the processes for forming the electrode material layer 631 are similar to those described with reference to FIG. 14, and thus details thereof are omitted for the sake of brevity. The inner material and the outer material may have different electrical conductivities. The inner material may include titanium nitride (TiN), titanium silicon nitride (TiSiN), tantalum nitride (TaN), or the likes, or combinations thereof, while the outer material may include silicon oxide, and/or silicon. It is noted that the inner material facilitates growth of the outer material on the electrode material layer 631. Any suitable deposition processes known in the art may be adopted to form the inner material layer 6321 and the outer material layer 6322. In some embodiments, a combination of the inner material layer 6321 and the outer material layer 6322 may have a thickness ranging from about 0.5 nm to about 2 nm. Such thickness is limited by a distance between adjacent ones of the channel features 21′, so that a desired electrical properties of the resultant gate electrode 63 can be achieved.

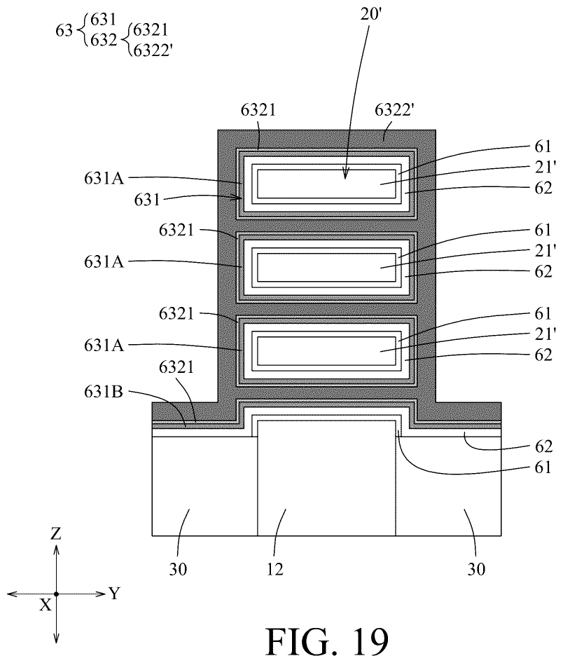

Referring to FIGS. 18 and 19, in the second stage of the second sub-step 107b, the outer material layer 6322 is subjected to the oxidation process to increase oxygen content in the outer material. Similarly, in such case, oxygen serves as the stressor material to expand the outer material. It is noted that, as the oxidation process proceeds, the different portions of the outer material layer 6322 continue to expand, and eventually, merge in a continuous manner to form an outer layer 6322′. The outer layer 6322′ and the inner material layer 6321 cooperatively form the stressor feature 632 as shown in FIG. 19. In some embodiments, the inner material layer 6321 has an electrical conductivity greater than an electrical conductivity of the outer layer 6322′. Similar to the compressive film as described in FIG. 15, the outer layer 6322′ also serves as a compressive film that is capable to alter lattice distance of silicon atoms in the channel features 21′ and to induce stress in the channel features 21′, thereby enhancing electron mobility. In such case, the electrode material layer 631 and the stressor feature 632 cooperatively form the gate electrode 63. It is noted that, oxygen is distributed among the outer material throughout the entire outer layer 6322′, so as to ensure the gate electrode 63 has uniform electrical properties. In addition, oxygen content in other elements of the structure, e.g., the electrode material layer 631, the channel features 21′, the gate dielectric 62, the ILs 61, remains at similar level after formation of the stressor feature 632, indicating that the oxidation process is controlled such that the other elements of the structure are minimally affected. Other details regarding the oxidation process is similar to those described with reference to FIG. 15, and thus are not repeated for the sake of brevity.

Referring to FIGS. 20 and 21, the third sub-step 107c of forming the filling electrode 64 on the gate electrode 63 is performed, and is similar to that described with reference to FIG. 16, and thus details thereof are not repeated for the sake of brevity. As such, the semiconductor structure including the stressor feature 632 in the gate electrode 63 is obtained. In some embodiments, the oxygen accounts for about 20 atomic percentage to about 50 atomic percentage based on total atoms in the outer layers 6322′. In each of the electrode material layer 631, the filling electrode 64, and the channel features 21′ where the oxygen is not introduced thereto in the aforementioned oxidation process, oxygen may account for less than about 10 atomic percentage based on total atoms in each of the electrode material layer 631, the filling electrode 64, and the channel features 21′.

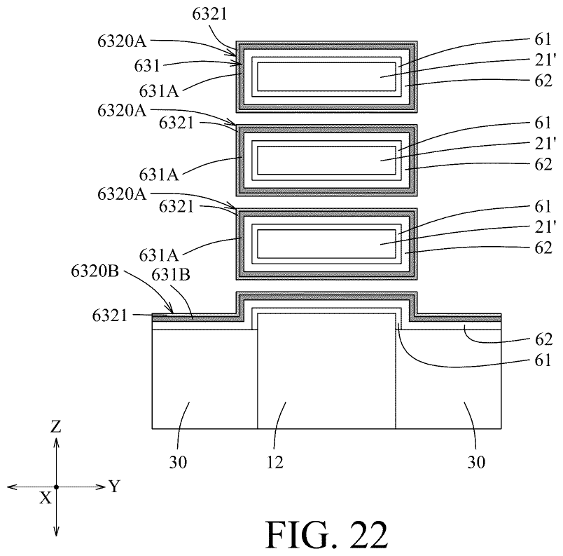

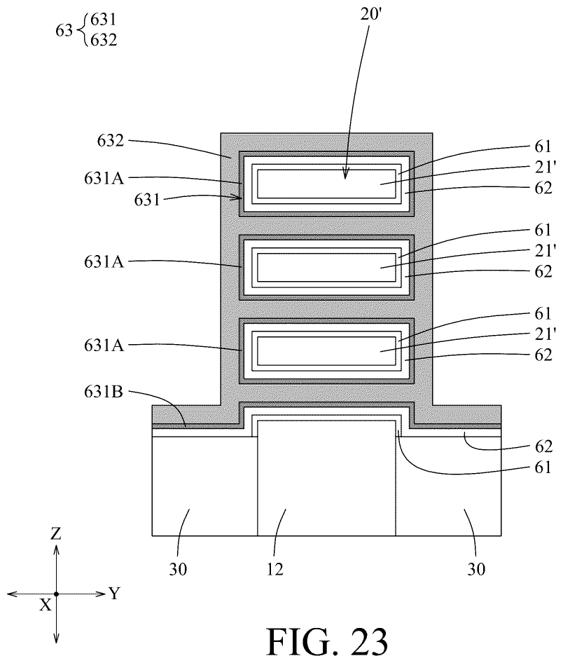

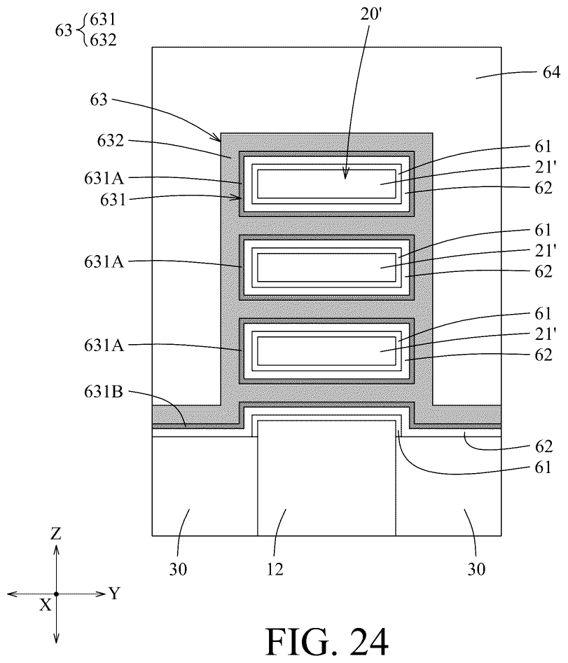

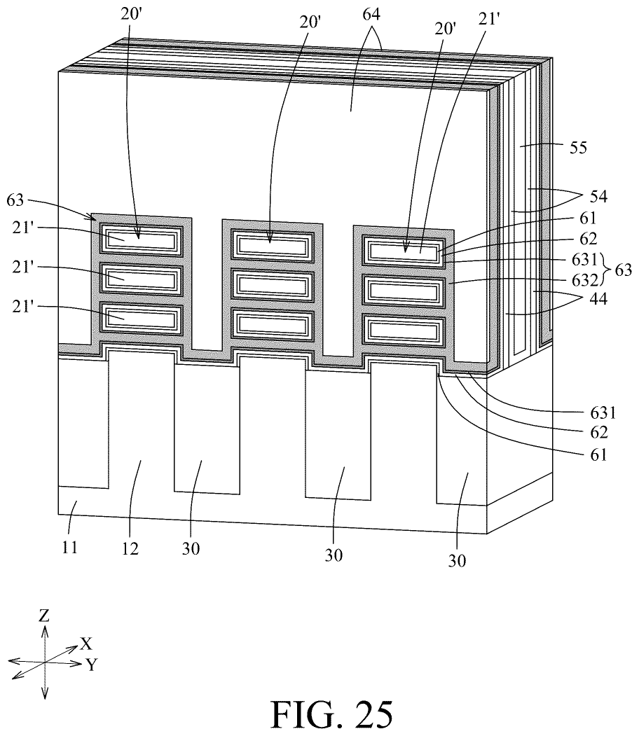

The stressor feature 632 may also be modified in that the stressor feature 632 includes merely the inner material, and that the stressor material is directly introduced into the inner material. FIGS. 22 to 25 are views respectively corresponding to those of FIGS. 18 to 21, and illustrate such modification. Referring to FIG. 22, in some other embodiments, in the first stage of the second sub-step 107b, the outer material layer 6322 may be omitted (see also FIG. 18). The stressor portions 6320A and the stressor bottom portion 6320B are spaced apart from each other. Referring to FIG. 23, in the second stage, the inner material layer 6321 is subjected to the oxidation process, i.e., oxygen is introduced into the inner material and causes expansion thereof. The different portions of the inner material layer 6321 continue to expand and eventually merge in a continuous manner, thereby forming the stressor feature 632, and thus the gate electrode 63. Similar to the compressive film as described in FIG. 15, the stressor feature 632 also serves as a compressive film that is capable of altering lattice distance of silicon atoms in the channel features 21′ and inducing stress in the channel features 21′, thereby enhancing electron mobility. It is noted that, oxygen is distributed among the inner material throughout the entire stressor feature 632, so as to ensure the gate electrode 63 has uniform electrical properties. In addition, oxygen content of other elements of the structure, e.g., the inner material layer 6321, the electrode material layer 631, the channel features 21′, the gate dielectric 62, the ILs 61, remains at similar level after formation of the gate electrode 63, indicating that the oxidation process is controlled such that the other elements of the structure is minimally affected. Other details regarding the oxidation process is similar to those described in FIGS. 15 and 19, and thus are not repeated for the sake of brevity. Referring to FIGS. 24 and 25, the third sub-step 107c of forming the filling electrode 64 on the gate electrode 63 is performed, and is similar to that described with reference to FIGS. 16 and 20. In some embodiments, the oxygen accounts for about 20 atomic percentage to about 50 atomic percentage based on total atoms in the stressor feature 632. In each of the electrode material layer 631, the filling electrode 64, and the channel features 21′ where the oxygen is not introduced thereto in the aforementioned oxidation process, oxygen may account for less than about 10 atomic percentage based on total atoms in each of the electrode material layer 631, the filling electrode 64, and the channel features 21′.

In the discussion above, oxygen serves as the stressor material that is introduced into the first electrode material, the outer material, or the inner material through the oxidation process. It should be noted that the stressor material may also be other chemical species such that the gate electrode 63 becomes compressive, thereby lengthening lattice distance (in the longitudinal direction (X)) in the channel features 21′ and generating stress therein to enhance electron mobility. For instance, in some other embodiments, the stressor material is a dopant that is in-situ doped during deposition of the first electrode material, the outer material or the inner material. Examples of the dopant are fluorine, aluminum, tantalum, carbon, silicon, nitrogen, or combinations thereof. These species are found to cause minor impacts to electrical properties of the resultant gate electrode 63. After the doping process, the stressor material, i.e., the dopant, accounts for about 10 atomic percentage to about 40 atomic percentage based on 100 atomic percentage of the first electrode material (or the outer material, or the inner material) and the stressor material (dopant). Such range merely has minor impact on electrical properties of the gate electrode 63, while the gate electrode 63 is compressive enough to generate sufficient stress in the channel features 21′ for enhancing electron mobility. In another embodiments, the dopants serving as the stressor material may also be introduced into the first electrode material, the outer material or the inner material though an ex-situ doping process.

In the first stage of the second sub-step 107b, the electrode material layer 631 described in FIG. 14, the outer material layer 6322 described in FIG. 18, and the inner material layer 6321 described in FIG. 22 are each in-situ doped with the dopant (i.e., the stressor material). That is, in the exemplary embodiment shown in FIG. 14, the first electrode material is deposited in presence of the dopant, so that the resultant electrode material layer 631 expands and becomes compressive. Similarly, in FIG. 18, the outer material is deposited in presence of the dopant, so that the resultant outer material layer 6322 expands and becomes compressive; and in FIG. 22, the inner material is deposited in presence of the dopant, so that the resultant inner material layer 6321 expands and becomes compressive. It should be noted that other details regarding the first stage of the second sub-step 107b are the same as described in the foregoing, e.g., that the electrode portions 631A, or the stressor portions 6320A should be spaced apart from each other so as to allow sufficient space for expansion thereof in the subsequent oxidation process. The subsequent second stage of the second sub-step 107b, and the third sub-step 107c remain the same as aforementioned, and are not repeated for the sake of brevity. In short, both in-situ doping and oxidation may be performed to allow the gate electrode 63 to become compressive, so as to generate an ideal stress level in the channel features 21′.

According to practical needs, one may also determine to include only one type of the aforementioned stressor materials in the gate electrode 63. For instance, one may decide to adopt merely the dopant as the stressor material to be included in the gate electrode 63. In such case, the second sub-step of forming the material layers that have portions being spaced apart from each other (the first stage), and the oxidation process (the second stage) are omitted. Instead, the second sub-step 107b includes forming the gate electrode 63 which includes the first electrode material and the stressor material, and which is in-situ doped with the stressor material (i.e., the dopant(s)). Details regarding the first electrode material and the dopants are similar as aforementioned and are not repeated for the sake of brevity. For instance, in some embodiments, in order to obtain the gate electrode 63 that includes merely the first electrode material and the dopant (i.e., not including the stressor feature 632), the deposition of the first electrode material in-situ doped with the stressor material continues until the gate electrode 63 shown in FIG. 15 is obtained. In other embodiments, in order to obtain the gate electrode 63 that includes the first electrode material, the dopant, the stressor feature 632 having both the inner material and the outer material, the first electrode material and the inner material are sequentially deposited so as to form the electrode material layer 631 and the inner material layer 6321, followed by deposition of the outer material that is in-situ doped with the stressor material (i.e., the dopants), so as to form the outer layer 6322′, thereby obtaining the stressor feature 632 and thus the gate electrode 63 as shown in FIG. 19. In some other embodiments, in order to obtain the gate electrode 63 that includes the electrode material layer 631, and the stressor feature 632 having merely the inner material and the dopant, the electrode material layer 631 is first formed, followed by performing the in-situ doping during deposition of the inner material, so as to form the stressor feature 632 and thus the gate electrode 63 as shown in FIG. 23. After forming the gate electrode 63, the sub-step 107d of forming the filling electrode 64 is performed so as to obtain the active gate and thus the semiconductor structures as shown in FIGS. 17, 21 and 25.

The embodiments of the present disclosure have the following advantageous features. The semiconductor structure includes the gate electrode 63, which includes a portion made of a first electrode material, and optionally a stressor feature 632 that is made of an inner material, and further optionally an outer material different from the inner material. Oxygen and/or a selected dopant is (are) introduced into one of the first electrode material, the inner material, and the outer material using different processes, so that at least one portion of the resultant gate electrode 63 becomes compressive. After forming the gate electrode 63 that is compressive, a lattice distance in the channel features 21′ is lengthened in the longitudinal direction (X), so as to generate a stress in the channel features 21′, thereby enhancing electron mobility, and thus performance of the n-type semiconductor structure.

In accordance with some embodiments of the present disclosure, a method for manufacturing a semiconductor structure includes: forming a nanosheet stack which includes sacrificial layers and channel layers that are alternately stacked on each other; forming a gate structure over the nanosheet stack, such that two stack portions of the nanosheet stack are respectively located at two opposite sides of the gate structure; removing the two stack portions to form two source/drain recesses at the two opposite sides of the gate structure so that the channel layers are respectively formed into channel features and the sacrificial layers are respectively formed into sacrificial features; forming two source/drain portions respectively in the two source/drain recesses; removing a dummy gate of the gate structure and the sacrificial features; and after removing the dummy gate and the sacrificial features, forming an gate electrode which is disposed between the two source/drain portions and around the channel features, the gate electrode including an electrode material and a stressor material different from the electrode material.

In accordance with some embodiments of the present disclosure, forming the gate electrode includes: depositing the electrode material to form an electrode material layer having electrode portions that are respectively located around the channel features, the electrode portions being spaced apart from each other; and performing a treatment to introduce the stressor material into the electrode material, so that the electrode portions expand and merge together, thereby forming the gate electrode.

In accordance with some embodiments of the present disclosure, the treatment includes an oxidation process.

In accordance with some embodiments of the present disclosure, the stressor material includes oxygen.

In accordance with some embodiments of the present disclosure, the oxygen accounts for more than 10 atomic percentage based on 100 atomic percentage of the electrode material and the stressor material.

In accordance with some embodiments of the present disclosure, the stressor material is in-situ doped during deposition of the electrode material.

In accordance with some embodiments of the present disclosure, the stressor material includes fluorine, aluminum, tantalum, carbon, silicon, nitrogen, or combinations thereof.

In accordance with some embodiments of the present disclosure, forming the gate electrode includes: forming an electrode material layer which includes the electrode material, the electrode material layer having electrode portions that are respectively located around the channel features, and that are spaced apart from each other; and forming a stressor feature which surrounds the electrode material layer, and which includes the stressor material.

In accordance with some embodiments of the present disclosure, the stressor feature includes an inner material layer and an outer layer which is disposed on the inner material layer opposite to the electrode material layer and which includes the stressor material, the inner material layer having an electrical conductivity greater than an electrical conductivity of the outer layer.

In accordance with some embodiments of the present disclosure, forming the stressor feature includes: forming stressor portions that are respectively located around the electrode portions, the stressor portions being spaced apart from each other; and performing a treatment to introduce the stressor material into the stressor portions, so that the stressor portions expand and merge together, thereby forming the stressor feature.

In accordance with some embodiments of the present disclosure, the stressor feature is formed by deposition of a material of the stressor feature in-situ doped with the stressor material.

In accordance with some embodiments of the present disclosure, a method for manufacturing a semiconductor structure includes: forming a nanosheet stack which includes sacrificial layers and channel layers that are alternately stacked on each other in a vertical direction; forming a gate structure over the nanosheet stack in a transverse direction, such that two stack portions of the nanosheet stack are respectively located at two opposite sides of the gate structure in a longitudinal direction, the vertical direction, the transverse direction and the longitudinal direction being transverse to each other; removing the two stack portions to form two source/drain recesses at the two opposite sides of the gate structure so that the channel layers are respectively formed into channel features and the sacrificial layers are respectively formed into sacrificial features; forming two source/drain portions respectively in the two source/drain recesses; removing a dummy gate of the gate structure and the sacrificial features; and after removing the dummy gate and the sacrificial features, forming a gate electrode which is disposed between the two source/drain portions and around the channel features, and which alters a lattice distance in the channel features in the longitudinal direction (X).

In accordance with some embodiments of the present disclosure, the gate electrode includes an electrode material layer including an electrode material, and a stressor feature including a stressor material that is different from the electrode material.

In accordance with some embodiments of the present disclosure, the stressor feature is formed after forming the electrode material layer.

In accordance with some embodiments of the present disclosure, the stressor feature includes an inner material layer and an outer layer which is disposed on the inner material layer opposite to the electrode material layer, the stressor material is distributed throughout the outer layer.

In accordance with some embodiments of the present disclosure, the gate electrode includes an electrode material and a stressor material, the stressor material being different from the electrode material and being distributed among the electrode material.

In accordance with some embodiments of the present disclosure, the stressor material includes a first stressor material and a second stressor material that are different from each other.

In accordance with some embodiments of the present disclosure, forming the gate electrode includes: depositing the electrode material, in which the first stressor material is in-situ doped, to form an electrode material layer having electrode portions that are respectively located around the channel features, the electrode portions being spaced apart from each other in the vertical direction; and performing an oxidation process to introduce the second stressor material into the electrode material layer, so that the electrode portions expand and merge in a continuous manner, thereby forming the gate electrode.

In accordance with some embodiments of the present disclosure, a semiconductor structure includes: channel features that are stacked on each other in a vertical direction; two source/drain portions that are spaced apart from each other by the channel features; and a gate electrode. The gate electrode surrounds each of the channel features, and includes an electrode material and a stressor material different from the electrode material. The stressor material in at least one portion of the gate electrode accounts for more than 10 atomic percentage based on total atoms in the at least one portion of the gate electrode.

In accordance with some embodiments of the present disclosure, the gate electrode includes an electrode material layer including the electrode material, and a stressor feature including the stressor material. The stressor feature serves as the at least one portion of the gate electrode, and is disposed on the electrode material layer opposite to the channel features.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor structure, comprising:
forming a nanosheet stack which includes sacrificial layers and channel layers that are alternately stacked on each other;
forming a gate structure over the nanosheet stack, such that two stack portions of the nanosheet stack are respectively located at two opposite sides of the gate structure;
removing the two stack portions to form two source/drain recesses at the two opposite sides of the gate structure so that the channel layers are respectively formed into channel features and the sacrificial layers are respectively formed into sacrificial features;
forming two source/drain portions respectively in the two source/drain recesses;
removing a dummy gate of the gate structure and the sacrificial features; and
after removing the dummy gate and the sacrificial features, forming a gate electrode which is disposed between the two source/drain portions and around the channel features, the gate electrode including an electrode material and a stressor material different from the electrode material.

2. The method according to claim 1, wherein forming the gate electrode includes:
depositing the electrode material to form an electrode material layer having electrode portions that are respectively located around the channel features, the electrode portions being spaced apart from each other; and
performing a treatment to introduce the stressor material into the electrode material, so that the electrode portions expand and merge together, thereby forming the gate electrode.

3. The method according to claim 2, wherein the treatment includes an oxidation process.

4. The method according to claim 1, wherein the stressor material includes oxygen.

5. The method according to claim 4, wherein the oxygen accounts for more than 10 atomic percentage based on 100 atomic percentage of the electrode material and the stressor material.

6. The method according to claim 1, wherein the stressor material is in-situ doped during deposition of the electrode material.

7. The method according to claim 1, wherein the stressor material includes fluorine, aluminum, tantalum, carbon, silicon, nitrogen, or combinations thereof.

8. The method according to claim 1, wherein forming the gate electrode includes:
forming an electrode material layer which includes the electrode material, the electrode material layer having electrode portions that are respectively located around the channel features, and that are spaced apart from each other; and
forming a stressor feature which surrounds the electrode material layer, and which includes the stressor material.

9. The method according to claim 8, wherein the stressor feature includes an inner material layer and an outer layer which is disposed on the inner material layer opposite to the electrode material layer and which includes the stressor material, the inner material layer having an electrical conductivity greater than an electrical conductivity of the outer layer.

10. The method according to claim 8, wherein forming the stressor feature includes:
forming stressor portions that are respectively located around the electrode portions, the stressor portions being spaced apart from each other; and
performing a treatment to introduce the stressor material into the stressor portions, so that the stressor portions expand and merge together, thereby forming the stressor feature.

11. The method according to claim 8, wherein the stressor feature is formed by deposition of a material of the stressor feature in-situ doped with the stressor material.

12. A method for manufacturing a semiconductor structure, comprising:
forming a nanosheet stack which includes sacrificial layers and channel layers that are alternately stacked on each other in a vertical direction;
forming a gate structure over the nanosheet stack in a transverse direction, such that two stack portions of the nanosheet stack are respectively located at two opposite sides of the gate structure in a longitudinal direction, the vertical direction, the transverse direction and the longitudinal direction being transverse to each other;
removing the two stack portions to form two source/drain recesses at the two opposite sides of the gate structure so that the channel layers are respectively formed into channel features and the sacrificial layers are respectively formed into sacrificial features;
forming two source/drain portions respectively in the two source/drain recesses;
removing a dummy gate of the gate structure and the sacrificial features; and
after removing the dummy gate and the sacrificial features, forming a gate electrode which is disposed between the two source/drain portions and around the channel features, and which alters a lattice distance in the channel features in the longitudinal direction.

13. The method according to claim 12, wherein the gate electrode includes an electrode material layer including an electrode material, and a stressor feature including a stressor material that is different from the electrode material.

14. The method according to claim 13, wherein the stressor feature is formed after forming the electrode material layer.

15. The method according to claim 13, wherein the stressor feature includes an inner material layer and an outer layer which is disposed on the inner material layer opposite to the electrode material layer, the stressor material is distributed throughout the outer layer.

16. The method according to claim 12, wherein the gate electrode includes an electrode material and a stressor material, the stressor material being different from the electrode material and being distributed among the electrode material.

17. The method according to claim 16, wherein the stressor material includes a first stressor material and a second stressor material that are different from each other.

18. The method according to claim 17, wherein forming the gate electrode includes
depositing the electrode material, in which the first stressor material is in-situ doped, to form an electrode material layer having electrode portions that are respectively located around the channel features, the electrode portions being spaced apart from each other in the vertical direction; and
performing an oxidation process to introduce the second stressor material into the electrode material layer, so that the electrode portions expand and merge in a continuous manner, thereby forming the gate electrode.

19. A semiconductor structure, comprising:
channel features that are stacked on each other in a vertical direction;
two source/drain portions that are spaced apart from each other by the channel features; and
a gate electrode that surrounds each of the channel features, the gate electrode including an electrode material and a stressor material different from the electrode material, the stressor material in at least one portion of the gate electrode accounting for more than 10 atomic percentage based on total atoms in the at least one portion of the gate electrode.

20. The semiconductor structure according to claim 19, wherein:
the gate electrode includes an electrode material layer including the electrode material, and a stressor feature including the stressor material; and
the stressor feature serves as the at least one portion of the gate electrode, and is disposed on the electrode material layer opposite to the channel features.
